(19) United States
(12) Patent Application Publication
(10) Pub. No.: US 2004/0121609 A1
(43) Pub. Date: Jun. 24, 2004

(54) Method for forming silicon epitaxial layer

(75) Inventors: Tae Wan Lee, Seoul (KR); Kyu Jin Choi, Kyunggi-do (KR); Jung Hoon Sun, Kyunggi-do (KR); Sung Jin Whoang, Kyunggi-do (KR); Bok Won Cho, Kyunggi-do (KR)

Correspondence Address: OLIFF & BERRIDGE, PLC, P.O. BOX 19928, ALEXANDRIA, VA, 22320, US

(73) Assignee: JUSUNG ENGINEERING CO., LTD., KWANGJU-GUN (KR)

(21) Appl. No.: 10/724,187

(22) Filed: Dec. 1, 2003

(30) Foreign Application Priority Data
Dec. 2, 2002 (KR) 2002-75765

(51) Int. Cl. H01L 21/302; H01L 21/461

(52) U.S. Cl. 438/709

(57) ABSTRACT

Disclosed herein is a method for forming a silicon epitaxial layer. The method comprises the steps of cleaning the surface of a silicon substrate having dopant of predetermined concentration doped therein with mixed plasma comprising an etching gas containing fluorine and hydrogen or deuterium, and forming a silicon epitaxial layer on the cleaned surface of the silicon substrate. The doped concentration of the silicon substrate is preferably 10¹⁸ to 10²¹ atoms/cm³. According to the present invention, a new preliminary cleaning step is adopted, whereby a silicon epitaxial layer of good quality is formed on a highly doped silicon substrate at a low temperature of 700° C. or less.

### BACKGROUND OF THE INVENTION

1. Field of the Invention

The present invention relates to a method for forming a silicon epitaxial layer, and more particularly to a method for forming a silicon epitaxial layer of good quality on a highly doped silicon substrate at a low temperature of 700° C. or less.

2. Description of the Related Art

There inevitably exists a natural oxide film or other impurities on the surface of a silicon substrate even if the silicon substrate is carefully treated. On this account, a preliminary cleaning process for removing the natural oxide film formed on the surface of the silicon substrate is required to form an epitaxial layer on the surface of the silicon substrate.

A semiconductor device has been highly integrated, which requires a fine pattern of the sub-micron level or less. Especially, a fine pattern of approximately 0.1 μm is primarily required when a contact pad is formed to provide a bit line contact for electrically connecting a bit line and a drain at a cell transistor and to provide an align margin when a storage node contact for connecting a storage node and a source is formed. However, it is difficult to provided such a fine pattern of approximately 0.1 μm due to limitations of a photolithography process. In order to solve the above-mentioned problem, there has been newly proposed a selective epitaxial growth (hereinafter referred to as “SEG”) method, which is substituted for a conventional chemical vapor deposition (hereinafter referred to as “CVD”) method.

Generally, the SEG method is to selectively form an epitaxial layer only on a highly doped silicon substrate. At this time, a wet cleaning process is not sufficient to grow the epitaxial layer on the surface of the highly doped silicon substrate. Consequently, a preliminary cleaning process, such as a low-pressure hydrogen baking process, is required to grow the epitaxial layer on the surface of the highly doped silicon substrate.

FIGS. 1a to 1c are sectional views illustrating the conventional SEG method wherein a low-pressure hydrogen baking process is used as the preliminary cleaning process.

FIG. 1a illustrates a step for forming a dopant area 30. After a material layer pattern 20, such as an oxide film pattern or a nitride film pattern, is formed on the surface of a silicon substrate 10, the dopant area 30 is formed, by means of diffusion or ion implantation, on the other part of the surface of the silicon substrate 10 where the material layer pattern 20 is not formed.

FIG. 1b illustrates a preliminary cleaning step. The silicon substrate 10 having the dopant area 30 formed on the surface thereof is baked in a hydrogen atmosphere at a pressure of 1 to 760 Torr. At this time, it is required that the baking temperature be at least 900° C.

FIG. 1c illustrates a step for forming a silicon epitaxial layer 40. The epitaxial layer 40 is selectively formed on the dopant area 30. If an epitaxial growth condition is appropriately controlled, an epitaxial growth speed on the surface of the silicon substrate 10 is higher than that on the material pattern 20. Consequently, the epitaxial layer 40 can be selectively grown only on the dopant area 30 under such appropriately controlled epitaxial growth conditions.

The above-mentioned low-pressure hydrogen baking process is carried out at a high temperature of 900° C. or more, which is not preferable in terms of thermal budget.

To this end, an ultra high-vacuum annealing or hydrogen baking process has been proposed as the preliminary cleaning process. These processes have an advantage in that the processes are carried out at a temperature lower than that of the above-mentioned low-pressure hydrogen baking process. Nevertheless, the temperature at which the processes are carried out is still high. For example, the temperature is 700° C. or more. Also, it is very difficult to obtain the epitaxial layer 40 when the dopant concentration of the dopant area 30 is high, for example, 10¹⁸ to 10²¹ atoms/cm³. Furthermore, quality of the formed film is not good.

Another cleaning process has also been proposed which uses hydrogen plasma at a temperature of 700° C. or less. When this cleaning process is used as the preliminary cleaning process, however, it is very difficult to obtain the epitaxial layer 40 in the case that concentration of the dopant area 30 is high.

As can be easily understood from the above description, no epitaxial layer of good quality can be obtained on a highly doped silicon substrate at a temperature of 700° C. or less according to the conventional arts.

### SUMMARY OF THE INVENTION

Therefore, the present invention has been made in view of the above problems, and it is an object of the present invention to provide a method for forming a silicon epitaxial layer including a preliminary cleaning step, which is carried out at a low temperature, so that a silicon epitaxial layer of good quality is formed on a highly doped silicon substrate at a low temperature of 700° C. or less.

In accordance with the present invention, the above and other objects can be accomplished by the provision of a method for forming a silicon epitaxial layer comprising the steps of: cleaning the surface of a silicon substrate having dopant of predetermined concentration doped therein with mixed plasma comprising an etching gas containing fluorine and hydrogen or deuterium; and forming a silicon epitaxial layer on the cleaned surface of the silicon substrate.

Preferably, the doped concentration of the silicon substrate is 10¹⁸ to 10²¹ atoms/cm³.

Preferably, the silicon epitaxial layer-forming step is carried out at a temperature of 550 to 700° C.

### BRIEF DESCRIPTION OF THE DRAWINGS

The above and other objects, features and other advantages of the present invention will be more clearly understood from the following detailed description taken in conjunction with the accompanying drawings, in which:

FIGS. 1a to 1c are sectional views illustrating the conventional SEG method wherein a low-pressure hydrogen baking process is used as a preliminary cleaning process; and

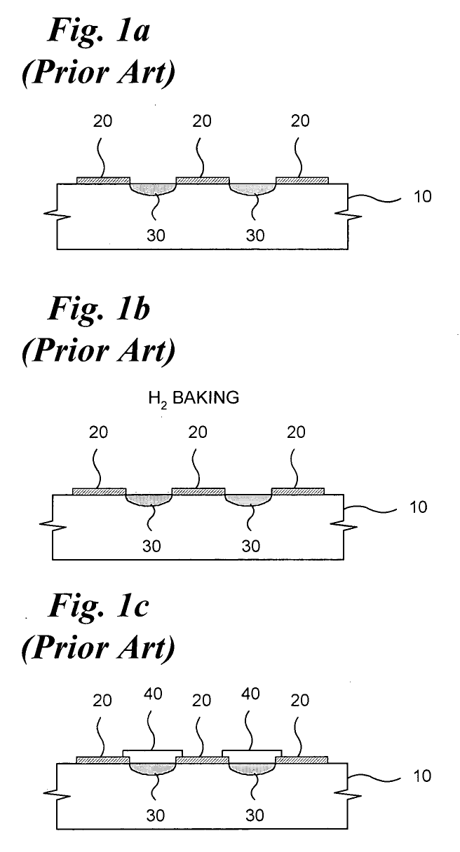

FIGS. 2a to 2c are sectional views illustrating a method for forming a silicon epitaxial layer according to a preferred embodiment of the present invention.

### DESCRIPTION OF THE PREFERRED EMBODIMENTS

Now, a preferred embodiment of the present invention will be described in detail with reference to the accompanying drawings.

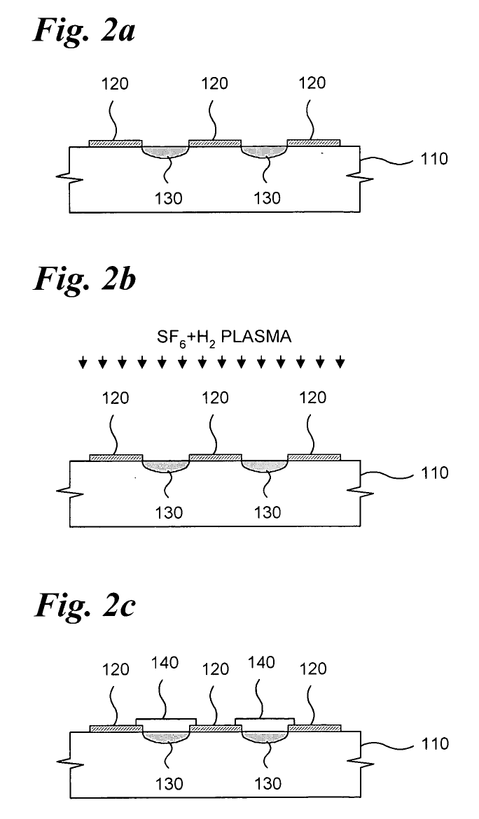

FIGS. 2a to 2c are sectional views illustrating a method for forming a silicon epitaxial layer according to a preferred embodiment of the present invention.

FIG. 2a illustrates a step for forming a dopant area 130. After a material layer pattern 120, such as an oxide film pattern or a nitride film pattern, is formed on the surface of a silicon substrate 110, the dopant area 130 is formed, by means of diffusion or ion implantation, on the other part of the surface of the silicon substrate 10 where the material layer pattern 120 is not formed. Boron, phosphorus, arsenic, or carbon may be used as the dopant. Concentration of the dopant area 130 is approximately 10¹⁸ to 10²¹ atoms/cm³ when the dopant area 30 is highly doped.

FIG. 2b illustrates a preliminary cleaning step. The surface of the silicon substrate 110 having the dopant area 130 formed thereof is treated with a mixed plasma comprised of hydrogen (H2) or deuterium (D2), and an etching gas containing fluorine (F), such as SF6, NF2, CF4, ClF3, HF, or CClF2, at a temperature of 25 to 800° C.

It is preferable that the plasma treatment is carried out under a pressure of 1 mTorr to 1 Torr. Preferably, the ratio of the flow rate of SF6 to H2 is 1/10 to 1/1000 when the mixed plasma comprising SF6 and H2 is used. As the mixed plasma may be preferably used remote plasma in order to prevent the dopant area 130 from being damaged due to the plasma.

FIG. 2c illustrates a step for forming a silicon epitaxial layer 140. The epitaxial layer 140 is selectively formed on the dopant area 130. If an epitaxial growth condition is appropriately controlled, an epitaxial growth speed on the surface of the silicon substrate 110 is higher than that on the material pattern 120. Consequently, the epitaxial layer 140 can be selectively grown only on the dopant area 130 in such an appropriately controlled epitaxial growth condition. The epitaxial layer 140 can be formed at a temperature of 550 to 700° C. after the preliminary cleaning step is carried out.

In the case that the silicon substrate 110 is exposed to the air after the preliminary cleaning step is carried out, the preliminary cleaning step is pointless. Consequently, it is preferable that the preliminary cleaning step shown in FIG. 2b and the step for forming the silicon epitaxial layer 140 shown in FIG. 2c are carried out in the same chamber. It is guaranteed that silicon substrate is not exposed to the air while the substrate is transferred in the case that the preliminary cleaning step and the step for forming the silicon epitaxial layer 140 are carried out separately in different chambers.

As apparent from the above description, the present invention provides a method for forming a silicon epitaxial layer including a new preliminary cleaning step, which is carried out at a low temperature, whereby a silicon epitaxial layer of good quality is formed on a highly doped silicon substrate at a low temperature of 700° C. or less.

Although the preferred embodiment of the present invention has been disclosed for illustrative purposes, those skilled in the art will appreciate that various modifications, additions and substitutions are possible, without departing from the scope and spirit of the invention as disclosed in the accompanying claims.

What is claimed is:

1. A method for forming a silicon epitaxial layer comprising the steps of:
cleaning the surface of a silicon substrate having dopant of predetermined concentration doped therein with mixed plasma comprising an etching gas containing fluorine and hydrogen or deuterium; and
forming a silicon epitaxial layer on the cleaned surface of the silicon substrate.

2. The method as set forth in claim 1, wherein the doped concentration of the silicon substrate is 10¹⁸ to 10²¹ atoms/cm³.

3. The method as set forth in claim 1, wherein the cleaning step is carried out under a pressure of 1 mTorr to 1 Torr.

4. The method as set forth in claim 1, wherein the etching gas containing fluorine is SE6.

5. The method as set forth in claim 4, wherein the ratio of the flow rate of SF6 to hydrogen is 1/10 to 1/1000.

6. The method as set forth in claim 1, wherein the cleaning step and the silicon epitaxial layer-forming step are carried out in the same chamber.

7. The method as set forth in claim 1, wherein the cleaning step and the silicon epitaxial layer-forming step are carried out separately in different chambers, and wherein the silicon substrate is not exposed to the air when the silicon substrate is transferred to form the epitaxial layer after the surface of a silicon substrate is cleaned with the plasma.

8. The method as set forth in claim 1, wherein the mixed plasma is remote plasma.

9. The method as set forth in claim 1, wherein the silicon epitaxial layer-forming step is carried out at a temperature of 550 to 700° C.
